(19) United States
(12) Patent Application Publication
(10) Pub. No.: US 2026/0058652 A1
(43) Pub. Date: Feb. 26, 2026

(54) OPERATION METHOD FOR ELECTRONIC DEVICE

(71) Applicant: InnoLux Corporation, Miao-Li County (TW)

(72) Inventors: Yang-Jui HUANG, Miao-Li County (TW); Hui-Ching YANG, Miao-Li County (TW); Tao-Sheng CHANG, Miao-Li County (TW); I-An YAO, Miao-Li County (TW)

(21) Appl. No.: 19/279,389

(22) Filed: Jul. 24, 2025

(30) Foreign Application Priority Data
Aug. 22, 2024 (CN) 202411158529.6

(51) Int. Cl. H03K 17/56

(52) U.S. Cl. CPC H03K 17/56

(57) ABSTRACT

An operation method for an electronic device includes steps of: providing a first transistor having a first end and a second end; providing a power consuming device electrically connected to the first end of the first transistor; and providing a signal source electrically connected to the second end of the first transistor, wherein, in a frame time including a writing period and an output period, the signal source provides a high voltage level during the output period, and the signal source provides a low voltage level during the writing period.

### CROSS-REFERENCE TO RELATED APPLICATIONS

This application claims the benefits of the Chinese Patent Application Serial Number 202411158529.6, filed on Aug. 22, 2024, the subject matter of which is incorporated herein by reference.

### BACKGROUND

### Field of the Application

The present application relates to an operation method and, more particularly, to an operation method for an electronic device having an array circuit.

### Description of Related Art

In general, pixel array circuits usually update data sequentially and maintain data continuity through energy storage elements (such as capacitors) in the array. Although such a data updating method may increase the duration for converting data into output energy, for some electronic devices with power consuming devices, such as exposure devices or three-dimensional printing devices, these electronic devices often need to perform overall data updates (such as data updates for all array units). Therefore, if the prior sequential data updating method is used, it is possible that, due to the influence of the material properties of the elements in the array circuit, the array units that have not yet received data in the array may be influenced by the data received by other array units, resulting in uneven data updates for the entire array.

Therefore, there is a need to provide a novel operation method for an electronic device to alleviate and/or obviate the above problems.

### SUMMARY

The present application provides an operation method for an electronic device, which includes steps of: providing a first transistor having a first end and a second end; providing a power consuming device electrically connected to the first end of the first transistor; and providing a signal source electrically connected to the second end of the first transistor, wherein, in a frame time including a writing period and an output period, the signal source provides a high voltage level during the output period, and the signal source provides a low voltage level during the writing period.

The present application further provides an operation method for an electronic device, which includes steps of: providing a first transistor having a first end, a second end and a control end; providing a power consuming device electrically connected to the second end of the first transistor; and providing a first signal source electrically connected to the control end of the first transistor, wherein, in a frame time including a writing period and an output period, the first signal source provides a high voltage level during the output period, and the first signal source provides a low voltage level during the writing period.

The present application further provides an operation method for an electronic device, which includes steps of: providing a first transistor including a first end and a second end; providing a power consuming device electrically connected to the first end of the first transistor; and providing a signal source electrically connected to the second end of the first transistor, wherein, in a frame time including a writing period and an output period, the signal source provides a low voltage level during the output period, and the signal source provides a high voltage level during the writing period.

Other novel features of the application will become more apparent from the following detailed description when taken in conjunction with the accompanying drawings.

### BRIEF DESCRIPTION OF DRAWINGS

FIG. 1 is a schematic diagram of an electronic device according to an embodiment of the present application;

FIG. 2A is a timing diagram of the signals corresponding to FIG. 1 according to an embodiment of the present application;

FIG. 2B is a timing diagram of the signals corresponding to FIG. 1 according to another embodiment of the present application;

FIG. 3 is a schematic diagram of an electronic device according to another embodiment of the present application;

FIG. 4A is a timing diagram of the signals corresponding to FIG. 3 according to an embodiment of the present application;

FIG. 4B is a timing diagram of the signals corresponding to FIG. 3 according to another embodiment of the present application;

FIG. 5 is a schematic diagram of an electronic device according to another embodiment of the present application;

FIG. 6A is a timing diagram of the signals corresponding to FIG. 5 according to an embodiment of the present application;

FIG. 6B is a timing diagram of the signals corresponding to FIG. 5 according to another embodiment of the present application;

FIG. 7 is a schematic diagram of an electronic device according to another embodiment of the present application;

FIG. 8A is a timing diagram of the signals corresponding to FIG. 7 according to an embodiment of the present application;

FIG. 8B is a timing diagram of the signals corresponding to FIG. 7 according to another embodiment of the present application;

FIG. 9 is a schematic diagram of an electronic device according to another embodiment of the present application;

FIG. 10A is a timing diagram of the signals corresponding to FIG. 9 according to an embodiment of the present application; and

FIG. 10B is a timing diagram of the signals corresponding to FIG. 9 according to another embodiment of the present application.

### DETAILED DESCRIPTION OF EMBODIMENT

Reference will now be made in detail to exemplary embodiments of the present application, examples of which are illustrated in the accompanying drawings. Wherever possible, the same reference numerals are used in the drawings and description to refer to the same or like parts.

Throughout the specification and the appended claims, certain terms may be used to refer to specific components. Those skilled in the art will understand that electronic device manufacturers may refer to the same components by different names. The present application does not intend to distinguish between components that have the same function but have different names. In the following description and claims, words such as “containing” and “comprising” are open-ended words, and should be interpreted as meaning “including but not limited to”.

The terms, such as “about”, “substantially” or “approximately”, are generally interpreted as within 10% of a given value or range, or as within 5%, 3%, 2%, 1% or 0.5% of a given value or range.

The term “electrical connection” includes any direct and indirect electrical connection means. The electrical connection between two components may be direct contact to transmit electrical signals without any other components therebetween. Alternatively, the electrical connection between two components may be bridged by a component in between to transmit electrical signals. “Electrical connection” may also be referred to as “coupling”.

In the specification and claims, unless otherwise specified, ordinal numbers, such as “first” and “second”, used herein are intended to distinguish elements rather than disclose explicitly or implicitly that names of the elements bear the wording of the ordinal numbers. The ordinal numbers do not imply what order an element and another element are in terms of space, time or steps of a manufacturing method. Thus, what is referred to as a “first element” in the specification may be referred to as a “second element” in the claims.

In the present application, the expressions “the given range is from the first numerical value to the second numerical value” and “the given range falls within the range from the first numerical value to the second numerical value” indicate that the given range includes the first numerical value, the second value, and other values therebetween.

In addition, the electronic device disclosed in the present application may include an exposure device, a printing device, a three-dimensional printing device, a display device, a vehicle device, an imaging device, an assembly device, a backlight device, an antenna device, a tiled device, a touch display, a curved display, or a free shape display, but not limited thereto. The electronic device may include, for example, liquid crystal, light emitting diode, fluorescence, phosphor, other suitable display media, or a combination thereof, but not limited thereto. The display device may be a non-self-luminous display device or a self-luminous display device. The antenna device may be a liquid crystal type antenna device or a non-liquid crystal type antenna device, and the sensing device may be a sensing device that senses capacitance, light, heat energy, or ultrasound, but not limited thereto. The tiled device may include, for example, a display tiled device or an antenna tiled device, but not limited thereto. It should be noted that the electronic device may be any arrangement or combination of the aforementioned, but not limited thereto. In addition, the electronic device may be a bendable or flexible electronic device. It should be noted that the electronic device may be any arrangement or combination of the aforementioned, but not limited thereto. In addition, the shape of the electronic device may be rectangular, circular, polygonal, a shape with curved edges, or other suitable shapes. The electronic device may have peripheral systems such as a driving system, a control system, a light source system, etc. to support a display device, an antenna device, or a tiled device.

It is noted that the following are exemplary embodiments of the present application, but the present application is not limited thereto, while a feature of some embodiments can be applied to other embodiments through suitable modification, substitution, combination, or separation. In addition, the present application can be combined with other known structures to form further embodiments.

Unless otherwise defined, all terms (including technical and scientific terms) used herein have the same meaning as commonly understood by those skilled in the art related to the present application. It can be understood that these terms, such as those defined in commonly used dictionaries, should be interpreted as having meaning consistent with the relevant technology and the background or context of the present application, and should not be interpreted in an idealized or excessively formal way, unless there is a special definition in the embodiment of the present application.

In addition, the term “adjacent” in the specification and claims is used to describe mutual proximity, and does not necessarily mean mutual contact.

In addition, descriptions such as “when” or “while” in the present application represent aspects such as “now, before or after”, and are not limited to situations that occur at the same time. In the present application, similar descriptions such as “disposed on” refer to the corresponding positional relationship between the two components, and do not limit whether there is contact between the two components, unless otherwise specified. Furthermore, when the present application provides multiple functions, if the word “or” is used between the functions, it means that the functions may exist independently, but it does not exclude that multiple functions may exist simultaneously.

For the convenience of description, the following paragraphs will be given with the electronic device as the exposure device, printing device or three-dimensional printing device, but the present application is not limited thereto.

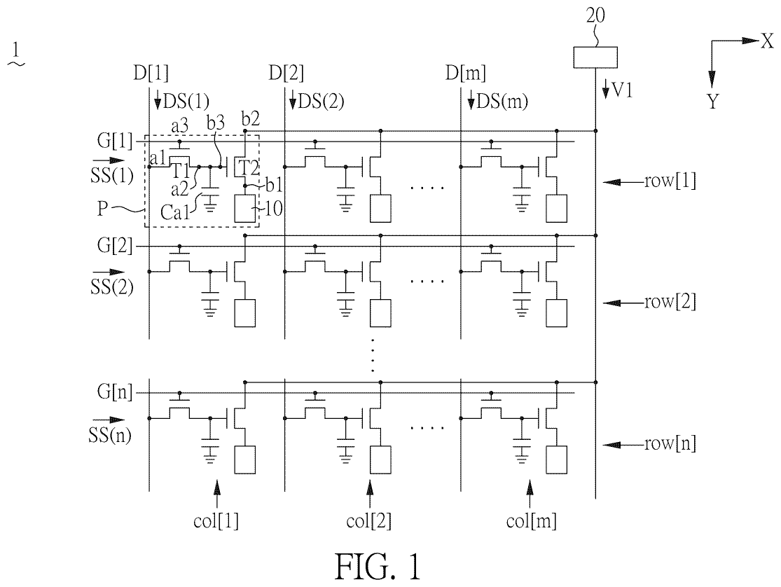

FIG. 1 is a schematic diagram of an electronic device 1 according to an embodiment of the present application. As shown in FIG. 1, the electronic device 1 may include n scan lines G[1]˜G[n] and m data lines D[1]˜D[m], where n and m are each a positive integer greater than 1. The n scan lines G[1]˜G[n] may extend along a first direction X, and the m data lines D[1]˜D[m] may extend along a second direction Y. The scan lines G[1]˜G[n] and the data lines D[1]˜D[m] may be arranged alternately to define a plurality of array units P (one array unit P may be considered as a pixel), and the plurality of array units P may form an array. The array formed by the array units P may include n rows row[1]˜row[n] and m columns col[1]˜col[m], and the n rows row[1]˜row[n] may be arranged sequentially along the second direction Y, wherein each of the rows row[1]˜row[n] may include m array units P, and the m columns col[1]˜col[m] may be arranged sequentially along the first direction X, wherein each of the columns col[1]˜col[m] may include n array units P, while the present application is not limited thereto.

In one embodiment, each array unit P may include a transistor T1, a transistor T2, a capacitor Ca1 and a power consuming device 10. The transistor T1 may include a first end a1, a second end a2 and a control end a3. The transistor T2 may include a first end b1, a second end b2 and a control end b3. The first end b1 of the transistor T2 may be electrically connected to the power consuming device 10, the second end b2 of the transistor T2 may be electrically connected to a signal source 20 to receive a first signal V1 provided by the signal source 20, and the control end b3 of the transistor T2 may be electrically connected to the second end a2 of the transistor T1 and the capacitor Ca1. The first end a1 of the transistor T1 may be electrically connected to one of the data lines D[1]˜D[m], and the control end a3 of the transistor T1 may be electrically connected to one of the scan lines G[1]˜G[n].

The transistor T1 or transistor T2 may be used as a switching element. In one embodiment, the type of the transistor T1 or transistor T2 may include N-type MOSFET (NMOS), P-type MOSFET (PMOS), bipolar junction transistor (BJT) or other types of transistors, but it is not limited thereto. For the convenience of explanation, the transistors T1 and T2 in FIG. 1 are exemplified by NMOS structures.

In one embodiment, the power consuming device 10 may be, for example, an electrode, a light emitting device, a heating device, a sensing device, a touch device, or a display device, or other devices that consume power, but it is not limited thereto. In one embodiment, the power consuming device 10 may receive energy via the transistor T2 and use the energy to perform power consumption. For example, the power consuming device 10 may convert the received energy (for example, at least a portion of the energy of the first signal V1) into heat energy, light energy, image display, etc., and then perform power consumption operations, but it is not limited thereto.

In one embodiment, the signal source 20 may be, for example, various power supply devices, such as a voltage source or a current source, but it is not limited thereto. In one embodiment, the signal source 20 may be, for example, a power source disposed outside the electronic device 1, but it is not limited thereto. The signal source 20 may be electrically connected to the second end b2 of the transistor T2 in each array unit P, so as to provide the first signal V1 to each array unit P. The voltage value of the first signal V1 may be adjusted through the signal source 20 itself or a control circuit connected to the signal source 20, but it is not limited thereto.

In one embodiment, the scan lines G[1]˜G[n] may be electrically connected to the same or different scan drivers (not shown), wherein the scan drivers may be used to provide scan signals SS(1)˜SS(n). For example, in the row row[1], the control end a3 of the transistor T1 in each array unit P may receive a scan signal SS(1) through the scan line G[1], in the row row[2], the control end a3 of the transistor T1 in each array unit P may receive a scan signal SS(2) through the scan line G[2], and so on. The scan signals SS(1)˜SS(n) may be used to turn on or off the transistors T1.

In one embodiment, the data lines D[1]˜D[m] may be electrically connected to the same or different data drivers (not shown), wherein the data drivers may be used to provide data signals DS(1)˜DS(m). For example, in the column col[1], the first end a1 of the transistor T1 of each array unit P may receive a data signal DS(1) through the data line D[1], in the column col[2], the first end a1 of the transistor T1 of each array unit P may receive a data signal DS(2) through the data line D[2], and so on. In addition, in one embodiment, the control end b3 of the transistor T2 of each array unit P may receive at least a portion of the energy of the data signal DS(1)˜DS(m) through the transistor T1, wherein the voltage value of the first signal V1 that is transmitted to the power consuming device 10 through the transistor T2 may be changed due to the influence of the voltage value received by the control end b3. Therefore, it may be considered that the power consumed by the power consuming device 10 is determined according to the data signal DS(1)˜DS(m) received by the control end b3 of the transistor T2, but it is not limited thereto.

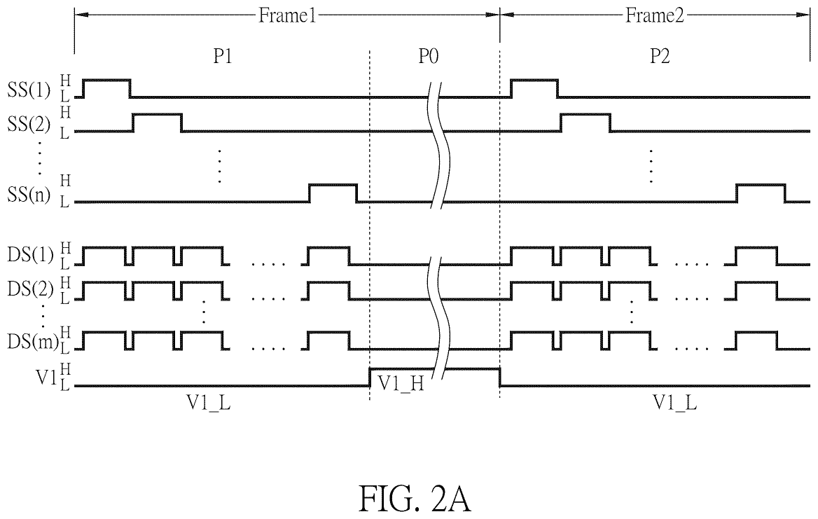

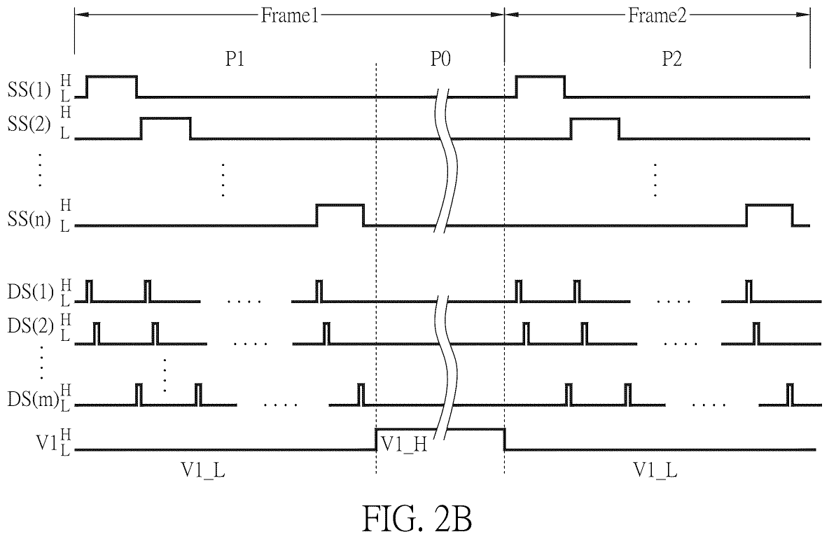

Next, the driving process of each component in the electronic device 1 is described. FIG. 2A is a timing diagram of the scan signals SS(1)˜SS(N), the data signals DS(1)˜DS(m) and the first signal V1 corresponding to the example of FIG. 1 according to an embodiment of the present application, and please refer to FIG. 1 at the same time. FIG. 2A may be used to illustrate the changes of the first signal V1, the data signals DS(1)˜DS(m) and the scan signals SS(1)˜SS(n) in at least one frame time Frame1 in the example of FIG. 1, wherein the “frame time Frame1” may be regarded as the time for the electronic device 1 to perform an overall data update, but it is not limited thereto.

As shown in FIG. 2A, the frame time Frame1 may include a writing period P1 and an output period P0, wherein the output period P0 follows the writing period P1. The next frame time Frame2 may follow the output period P0 of the frame time Frame1, wherein the frame time Frame2 may include a writing period P2 and an output period (not shown). Accordingly, the output period P0 of the frame time Frame1 may be disposed between the writing period P1 of the frame time Frame1 and the writing period P2 of the frame time Frame2.

Please refer to FIG. 1 and FIG. 2A at the same time. In one embodiment, in the writing period P1 of the frame time Frame1, the scan signals SS(1)˜SS(n) received by the rows row[1]˜row[n] may be sequentially changed from a low voltage level (for example, marked as L) to a high voltage level (for example, marked as H), and then sequentially changed from a high voltage level to a low voltage level. In the writing period P1, the data signals DS(1)˜DS(m) received by the columns col[1]˜col[m] may be synchronously changed from a low voltage level (for example, marked as L) to a high voltage level (for example, marked as H), and then synchronously changed from a high voltage level to a low voltage level, so that there is enough charging time to fully charge the capacitor to improve data integrity. In addition, in the writing period P1, the first signal V1 provided by the signal source 20 may maintain a low voltage level (for example, marked as V1_L), and in one embodiment, the voltage value of the low voltage level V1_L of the first signal V1 may be, for example, zero, but it is not limited thereto.

Furthermore, in one embodiment, in the writing period P1, the rows row[1]˜row[n] may sequentially receive scan signals SS(1)˜SS(n), and the transistor T1 of the array unit P in each row row[1]˜row[n] may receive its corresponding data signal DS(1)˜DS(m). In one embodiment, during the writing period P1, since the first signal V1 is maintained at a low voltage level V1_L, the power consuming device 10 does not receive the energy of the first signal V1 through the transistor T2, and the data signal DS(1)˜DS(m) received by each transistor T1 is stored in the capacitor Ca1 electrically connected thereto. At this moment, since the power consuming device 10 may not obtain sufficient energy through the transistor T2, the power consuming device 10 does not perform power consumption operations, wherein the power consumption refers to operations such as light emission, heat generation, or image display, but it is not limited thereto. In addition, in one embodiment, when all scan signals SS(1)˜SS(n) have changed from a low voltage level to a high voltage level and then from a high voltage level to a low voltage level, the energy stored in the capacitors Ca1 in the array units P in all rows row[1]˜row[n] may reach a threshold value, and the transistors T2 in the array units P in all rows row[1]˜row[n] are turned on. At this moment, the operation of the electronic device 1 may enter the output period P0, and the first signal V1 may change from a low voltage level V1_L to a high voltage level V1_H.

In one embodiment, in the output period P0, the scan signals SS(1)˜SS(n) may be at a low voltage level, the data signals DS(1)˜DS(m) may be at a low voltage level, the transistors T1 of the array units P in each row row[1]˜row[n] may be turned off, and the first signal V1 may be at a high voltage level V1_H. At this moment, for each array unit P, the control end b3 of the transistor T2 may receive the data signal DS(1)˜DS(m) stored in the capacitor Ca1, so that the transistor T2 may be turned on, and at least a portion of the energy of the first signal V1 may be transmitted to the power consuming device 10 through the transistor T2, so that the power consuming device 10 may use the received energy to perform power consumption operations, wherein the magnitude of the above energy (for example, the voltage value of the first signal V1 after passing through the transistor T2) may be determined according to the data signal DS(1)˜DS(m) received by the control end b3 of the transistor T2, while it is not limited thereto.

In one embodiment, in the output period P0, the scan signals SS(1)˜SS(n) may be at a low voltage level, and the voltage values thereof may be, for example, zero, but it is not limited thereto. In one embodiment, in the output period P0, the data signals DS(1)˜DS(m) may be at a low voltage level, and the voltage values thereof may be, for example, zero, but it is not limited thereto.

It can be seen that in the writing period P1, the power consuming device 10 of each array unit P does not perform power consumption operations. Therefore, the present application may alleviate the problem of uneven overall data update caused by the array units P that have not yet performed power consumption being affected by other array units P that have already performed power consumption. Alternatively, in the output period P0, the transistor T2 of each array unit P may be synchronously turned on to transmit at least a portion of the energy of the first signal V1 to the power consuming device 10, so that the power consuming device 10 of each array unit P may perform power consumption operations simultaneously, thereby achieving overall data update without delay. Therefore, the present application may solve the deficiencies of the prior art, but it is not limited thereto.

FIG. 2B is a timing diagram of the scan signals SS(1)˜SS(N), data signals DS(1)˜DS(m) and first signal V1 corresponding to the example of FIG. 1 according to another embodiment of the present application, and please refer to FIG. 1 and FIG. 2A at the same time. The timing of the scan signals SS(1)˜SS(N) and the first signal V1 in the example of FIG. 2B is generally applicable to the description of the example of FIG. 2A, and thus a detailed description is deemed unnecessary. The following mainly describes the timing of the data signals DS(1)˜DS(m).

As shown in FIG. 2B, in the writing period P1 of the frame time Frame1, the data signals DS(1)˜DS(m) may be sequentially changed from a low voltage level (L) to a high voltage level (H) during the period when each scan signal SS(1)˜SS(n) is at a high voltage level (H), and may be sequentially changed from a high voltage level to a low voltage level, thereby reducing the probability of data signals coupling with each other. With such a design, similar to the example of FIG. 2A, each power consuming device 10 may not perform energy consumption operation during the writing period P1. Alternatively, in the output period P0, each power consuming device 10 may perform power consumption operation simultaneously.

Please refer to FIG. 2A and FIG. 2B again. In one embodiment, the scan signals SS(1)˜SS(n) and/or the data signals DS(1)˜DS(m) may have a voltage rising time when they are converted from a low voltage level to a high voltage level, and during the voltage rising time, the scan signals SS(1)˜SS(n) and/or the data signals DS(1)˜DS(m) may gradually rise from a low voltage level to a high voltage level. In addition, the scan signals SS(1)˜SS(n) and/or the data signals DS(1)˜DS(m) may have a voltage falling time when they are converted from a high voltage level to a low voltage level, and during the voltage falling time, the scan signals SS(1)˜SS(n) and/or the data signals DS(1)˜DS(m) may gradually drop from a high voltage level to a low voltage level.

Furthermore, in one embodiment, in the writing period P1, when the scan signal SS(n) and/or the data signal DS(m) reaches a first preset condition during the voltage falling time, the operation of the electronic device 1 will enter the output period P0, wherein the first preset condition is that the scan signal SS(n) and/or the data signal DS(m) has dropped to more than 90% of the high voltage level (voltage value; 10% of the voltage value of the high voltage level), while it is not limited thereto. In addition, in one embodiment, in the output period P0, when the voltage rising time of the scan signal SS(1) and/or the data signal DS(1) reaches a second preset condition, the operation of the electronic device 1 will enter the writing period P2 of the next frame time Frame2. The second preset condition is that the voltage value of the scan signal SS(n) and/or the data signal DS(m) has risen from a low voltage level to more than 90% of the high voltage level (voltage value≥90% of the voltage value of the high voltage level), while it is not limited thereto.

In addition, according to FIG. 2A and FIG. 2B, an array unit P of the electronic device 1 of FIG. 1 may be operated by an operation method for an electronic device according to an embodiment of the present application, wherein the operation method for an electronic device may include the following steps:
Step A1: providing a transistor T2 including a first end b1 and a second end b2;
Step A2: providing a power consuming device 10 electrically connected to the first end b1 of the transistor T2;
Step A3: providing a signal source 20 electrically connected to the second end b2 of the transistor T2;
Step A4: in the frame time Frame1 having the writing period P1 and the output period P0, the signal source 20 providing a low voltage level V1_L in the writing period P1; and
Step A5: enabling the signal source 20 to provide a high voltage level V1_H during the output period P0.

In addition, in one embodiment, the operation method for an electronic device may further include step A6: providing a scan signal (for example, SS(1)), wherein the voltage level of the scan signal (for example, SS(1)) in the output period P0 is zero. In one embodiment, the operation method for an electronic device may further include step A7: providing a data signal (for example, DS(1)), wherein the voltage level of the data signal (for example, DS(1)) in the output period P0 is zero.

The order of the above steps A1 to A7 is not limited, as long as it is reasonable and achievable.

In addition, although the transistors T1 and T2 in the example of FIG. 1 are exemplified by NMOS structures, the present application may also have other implementations. For example, the transistors T1 and T2 may be PMOS structures. In this case, the transistors T1 and T2 may be turned on when the control ends a3 and b3 receive a low voltage, and may be turned off when the control ends a3 and b3 receive a high voltage, while it is not limited thereto.

As a result, the examples of FIG. 1 to FIG. 2B can be understood.

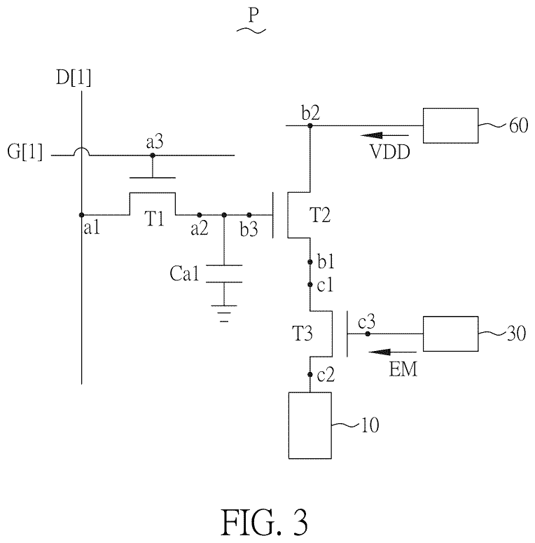

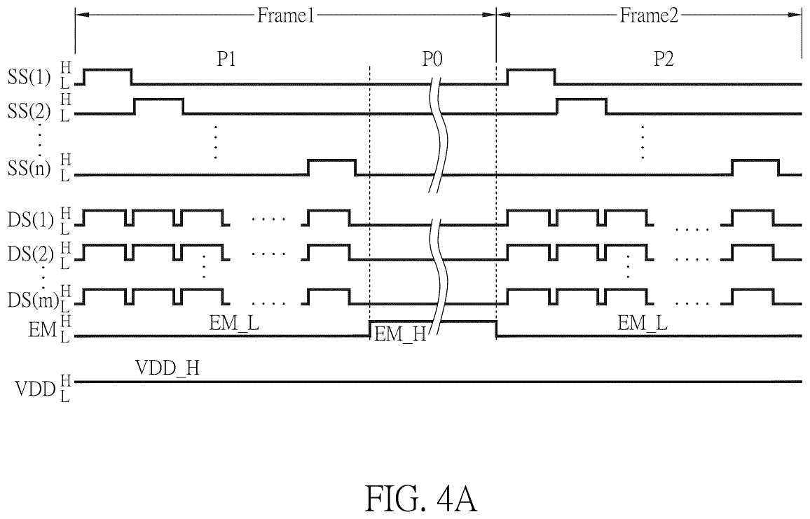

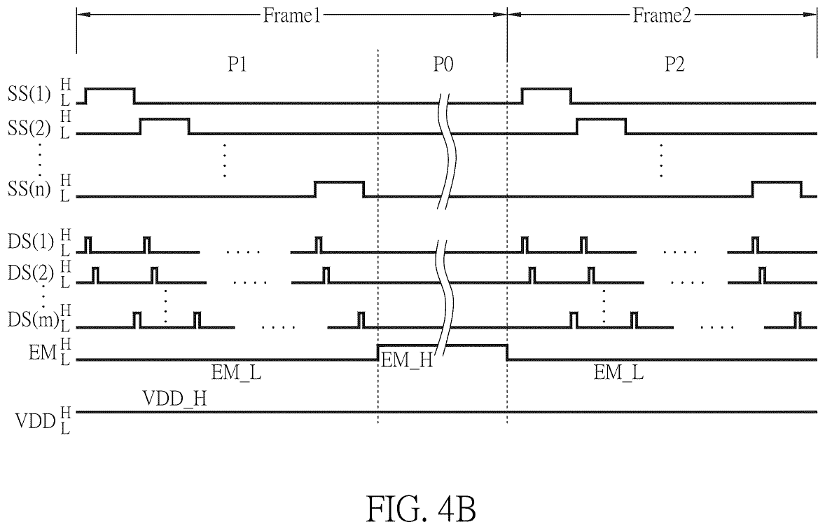

The electronic device 1 of the present application may also have different implementation aspects. FIG. 3 is a schematic diagram of an electronic device 1 according to another embodiment of the present application. FIG. 4A and FIG. 4B are timing diagrams of the scan signals SS(1)˜SS(N), data signals DS(1)˜DS(m), control signal EM and high voltage level signal VDD corresponding to the example of FIG. 3 according to an embodiment of the present application, and please also refer to FIG. 1 to FIG. 2B. For the convenience of explanation, FIG. 3 illustrates the circuit structure of an array unit P as an example, and those skilled in the art may infer the circuit state when a plurality of array units P of FIG. 3 form an array based on FIG. 1 and FIG. 3.

As shown in FIG. 3, the array unit P may include a transistor T1, a transistor T2, a capacitor Ca1 and a power consuming device 10, and the array unit P may further include a transistor T3. The transistor T2 may be electrically connected to a signal source 60. The transistor T3 may be electrically connected to a signal source 30. The transistor T3 has a first end c1, a second end c2 and a control end c3. The transistor T3 and the transistors T1 and T2 may have the same structure, for example, all are NMOS structures, but it is not limited thereto.

In one embodiment, the first end c1 of the transistor T3 may be electrically connected to the first end b1 of the transistor T2, the second end c2 of the transistor T3 may be electrically connected to the power consuming device 10, and the control end c3 of the transistor T3 may be electrically connected to the signal source 30, wherein the signal source 30 may be used to provide a control signal EM, and the control signal EM may be used to control the transistor T3 to be turned on or off. In addition, the second end b2 of the transistor T2 may be electrically connected to the signal source 60, wherein the signal source 60 may be used to provide a high voltage level signal VDD, and the control end b3 of the transistor T2 may be electrically connected to the capacitor Ca1 and the second end a2 of the transistor T1. The first end a1 of the transistor T1 may be electrically connected to one of the data lines D[1]˜D[m](for example, D[1]) to receive one of the data signals DS(l)˜DS(m) (for example, DS(l)). The control end a3 of the transistor T1 may be electrically connected to one of the scan lines G[1]˜G[n](for example, G[1]) to receive one of the scan signals SS(1)˜SS(m) (for example, SS(1)).

As shown in FIG. 1, FIG. 3 and FIG. 4A, in one embodiment, in the writing period P1 of the frame time Frame1, the scan signals SS(1)˜SS(n) are sequentially changed from a low voltage level (for example, marked as L) to a high voltage level (for example, marked as H), and the data signals DS(1)˜DS(m) are synchronously changed from a low voltage level (for example, marked as L) to a high voltage level (for example, marked as H). The transistors T1 in the rows row[1]˜row[n] may be turned on sequentially and each receives the corresponding data signal DS(1)˜DS(m). In one embodiment, during the writing period P1, the signal source 60 provides a high voltage level signal VDD, and the control signal EM provided by the signal source 30 is a low voltage level EM_L, so that the transistor T3 is turned off, and the data signal DS(1)˜DS(m) received by each transistor T1 is stored in the capacitor Ca1 electrically connected thereto, while the power consuming device 10 does not receive energy. Therefore, in the writing period P1, the power consuming device 10 does not perform power consumption operation.

Next, in one embodiment, in the output period P0 of the frame time Frame1, the scan signals SS(1)˜SS(n) are at a low voltage level, the data signals DS(1)˜DS(m) are at a low voltage level, the signal source 60 continues to provide the high voltage level signal VDD, and the control signal EM provided by the signal source 30 is converted to a high voltage level EM_H. At this moment, for each array unit P, the transistor T1 may be turned off, the control end b3 of the transistor T2 receives the data signal DS(1)˜DS(m) stored in the capacitor Ca1 and is turned on, and the transistor T3 is turned on because the control signal EM is a high voltage level EM_H, and then at least a portion of the energy of the high voltage level signal VDD may be transmitted to the power consuming device 10 through the transistor T2 and the transistor T3, whereby the power consuming device 10 may perform power consumption operation. In one embodiment, by adjusting the voltage values of the control signal EM and/or the data signals DS(1)˜DS(m), the power consumed by the power consuming device 10 (that is, the amount of energy received) may be adjusted, but it is not limited thereto.

Accordingly, the examples of FIG. 3 and FIG. 4A may be provided with similar effects as the examples of FIG. 1 to FIG. 2B so as to solve the problems of the prior art.

The timing of the scan signals SS(1)˜SS(n), the control signal EM and the high voltage level signal VDD of the example of FIG. 4B may be generally applicable to the description of the example of FIG. 4A, and the data signals DS(1)˜DS(m) of the example of FIG. 4B are sequentially changed from a low voltage level to a high voltage level and then sequentially changed from a high voltage level to a low voltage level during the period when the corresponding scan signals SS(1)˜SS(n) in the writing period P1 are changed to a high voltage level. Thus, the example of FIG. 4B may be provided with similar effects to the example of FIG. 4A, so as to solve the problems of the prior art.

According to the examples of FIG. 4A and FIG. 4B, an array unit P in the electronic device 1 of FIG. 3 may be operated by an operation method for an electronic device according to another embodiment of the present application, wherein the operation method for an electronic device may include the following steps:
Step B1: providing a transistor T3 including a first end c1, a second end c2 and a control end c3;
Step B2: providing a power consuming device 10 electrically connected to the second end c2 of the transistor T3;
Step B3: providing a signal source 30 electrically connected to the control end c3 of the transistor T3;
Step B4: in the frame time Frame1 having a writing period P1 and an output period P0, the signal source 30 providing a low voltage level EM_L in the writing period P1; and
Step B5: enabling the signal source 30 to provide a high voltage level EM_H in the output period P0.

In addition, in one embodiment, the operation method for an electronic device may further include step B6: providing a scan signal (for example, SS(1)), wherein the voltage level of the scan signal (for example, SS(1)) in the output period P0 is zero. In one embodiment, the operation method for an electronic device may further include step B7: providing a data signal (for example, DS(1)), wherein the voltage level of the data signal (for example, DS(1)) in the output period P0 is zero. In one embodiment, the operation method for an electronic device may further include step B8: enabling the signal source 60 to continuously provide the high voltage level signal VDD to the second end b2 of the transistor T2.

The order of the above steps B1 to B7 is not limited, as long as it is reasonable and achievable.

In addition, as long as it is reasonably achievable, the details of the timing of each signal in the examples of FIG. 4A and FIG. 4B may be applicable to the description in the examples of FIG. 2A and FIG. 2B.

Accordingly, the examples of FIG. 3 to FIG. 4B can be understood.

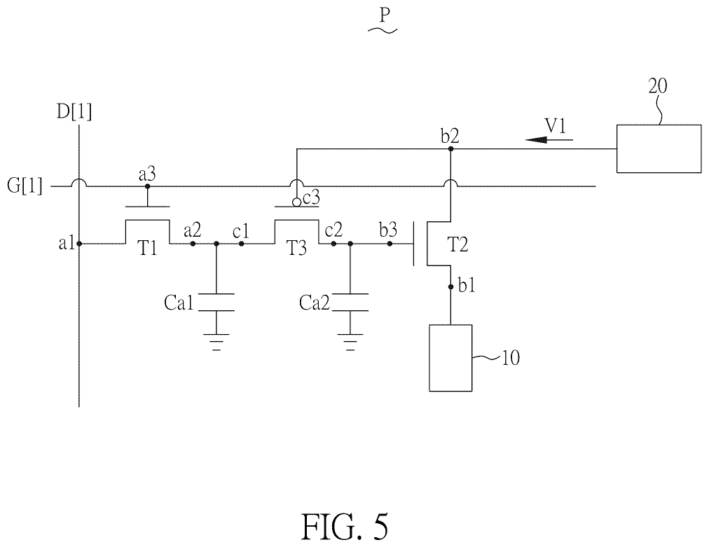

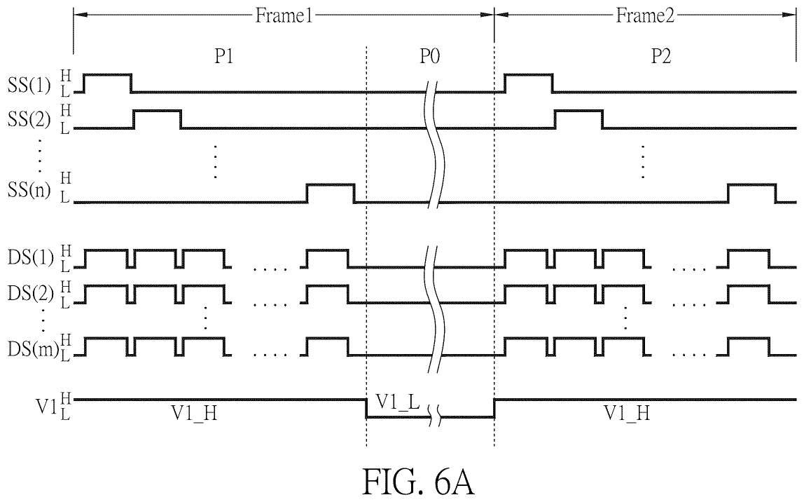

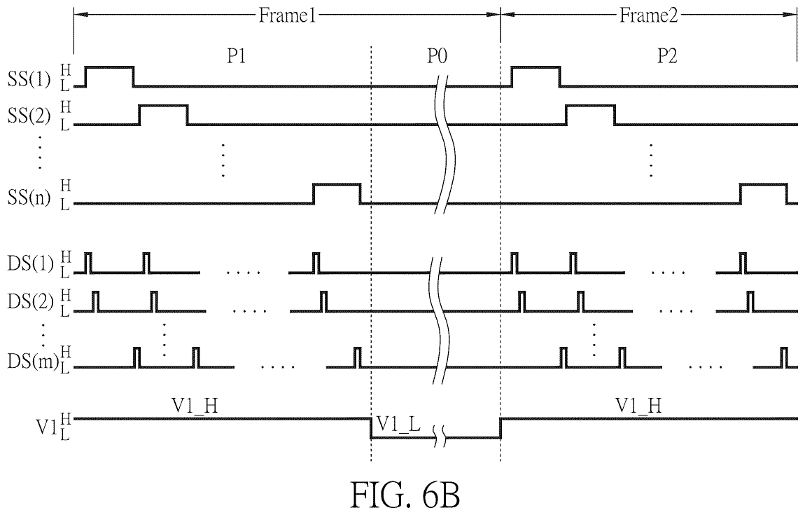

The electronic device 1 of the present application also has different implementation aspects. FIG. 5 is a schematic diagram of an electronic device 1 according to another embodiment of the present application. FIG. 6A and FIG. 6B are timing diagrams of the scan signals SS(1)˜SS(N), the data signals DS(1)˜DS(m) and the first signal V1 corresponding to the example of FIG. 5 according to an embodiment of the present application, and please also refer to FIG. 1 to FIG. 4B. For the convenience of explanation, FIG. 5 illustrates the circuit structure of an array unit P as an example, and those skilled in the art may infer the circuit state when a plurality of array units P of FIG. 5 form an array based on FIG. 1 and FIG. 5.

As shown in FIG. 5, the array unit P may include a transistor T1, a transistor T2, a capacitor Ca1, and a power consuming device 10, and may also include a transistor T3 and a capacitor Ca2. The transistor T3 has a first end c1, a second end c2 and a control end c3. The signal source 20 is used to provide a first signal V1. In addition, the transistor T3 and the transistors T1 and T2 may have different structures. For example, the transistor T3 may have a PMOS structure, and the transistors T1 and T2 may have an NMOS structure, but it is not limited thereto.

In one embodiment, the first end b1 of the transistor T2 may be electrically connected to the power consuming device 10, the second end b2 of the transistor T2 may be electrically connected to the signal source 20 to receive the first signal V1 provided by the signal source 20, and the control end b3 of the transistor T2 may be electrically connected to the capacitor Ca2 and the second end c2 of the transistor T3. The first end c1 of the transistor T3 may be electrically connected to the capacitor Ca1 and the second end a2 of the transistor T1, and the control end c3 of the transistor T3 may be electrically connected to the signal source 20 to receive the first signal V1. The first end a1 of the transistor T1 may be electrically connected to one of the data lines D[1]˜D[m](for example, D[1]) to receive one of the data signals DS(1)˜DS(m) (for example, DS(1)). The control end a3 of the transistor T1 may be electrically connected to one of the scan lines G[1]˜G[n](for example, G[1]) to receive one of the scan signals SS(1)˜SS(m) (for example, SS(1)).

As shown in FIG. 1, FIG. 5 and FIG. 6A, in one embodiment, in the writing period P1 of the frame time Frame1, the scan signals SS(1)˜SS(n) are sequentially changed from a low voltage level (for example, marked as L) to a high voltage level (marked as H), and the data signals DS(1)˜DS(m) are synchronously changed from a low voltage level (for example, marked as L) to a high voltage level (marked as H), and the transistors T1 in the rows row[1]˜row[n] are turned on sequentially and each receives the data signal DS(1)˜DS(m) corresponding to the frame time Frame1. In addition, in the writing period P1, the first signal V1 provided by the signal source 20 is a high voltage level V1_H, and the control end c3 of the transistor T3 of the PMOS structure receives the high voltage level V1_H, so that the transistor T3 is turned off. At this moment, the data signal DS(1)˜DS(m) corresponding to the frame time Frame1 received by the transistor T1 will be stored in the capacitor Ca1. In addition, since the transistor T3 is turned off, the transistor T2 will not receive the data signals DS(1)˜DS(m) corresponding to the frame time Frame1, so that the power consuming device 10 will not perform the power consumption operation corresponding to the frame time Frame1 in the writing period P1 of the frame time Frame1.

In one embodiment, in the output period P0 of the frame time Frame1, the scan signals SS(1)˜SS(n) are at a low voltage level, the data signals DS(1)˜DS(m) are at a low voltage level, and the first signal V1 changes from a high voltage level V1_H to a low voltage level V1_L. At this moment, for each array unit P, the transistor T3 of the PMOS structure may be turned on, and at least a portion of the energy of the data signal DS(1)˜DS(m) corresponding to the frame time Frame1 stored in the capacitor Ca1 may be stored in the capacitor Ca2 via the transistor T3. In addition, since the first signal V1 is at a low voltage level V1_L, the power consuming device 10 may not receive the energy of the first signal V1 through the transistor T2, and thus the power consuming device 10 does not perform power consumption operation in the output period P0 of the frame time Frame1.

In one embodiment, in the writing period P2 of the next frame time Frame2, the scan signals SS(1)˜SS(n) are sequentially changed from a low voltage level to a high voltage level, and the data signals DS(1)˜DS(m) are synchronously changed from a low voltage level to a high voltage level, so that the transistors T1 in the rows row[1]˜row[n] are turned on sequentially and each receives the data signal DS(1)˜DS(m) of the corresponding frame time Frame2. In addition, the first signal V1 provided by the signal source 20 is changed from the low voltage level V1_L to the high voltage level V1_H again. At this moment, for each array unit P, the transistor T3 of the PMOS structure is turned off. At this moment, the data signal DS(1)˜DS(m) corresponding to the frame time Frame2 received by the transistor T1 will be stored in the capacitor Ca1, and the control end b3 of the transistor T2 may receive at least a portion of the energy of the data DS(1)˜DS(m) corresponding to the frame time Frame1 that is stored in the capacitor Ca2, so that the transistor T2 may be turned on, and at least a portion of the energy of the first signal V1 may enter the power consuming device 10 through the transistor T2. In one embodiment, the power consumed by the power consuming device 10 may be determined according to the magnitude of the data signal DS(1)˜DS(m) corresponding to the frame time Frame1 received by the transistor T2, but it is not limited thereto. Therefore, in the writing period P2 of the frame time Frame2, the power consuming device 10 may perform the power consumption operation corresponding to the frame time Frame1.

In one embodiment, when the transistor T3 is turned on, the amount of charge received by the capacitor Ca1 and the capacitor Ca2 may reach a balance (for example, equal), but it is not limited thereto. In one embodiment, when the capacitance value of capacitor Ca1 is greater than or much greater than the capacitance value of capacitor Ca2 (for example, the difference between the two is at least 2 times, 5 times or 10 times, while it is not limited thereto), the data level (for example, voltage value) when the capacitor Ca1 and the capacitor Ca2 achieve charge balance may be adjusted by adjusting the capacitance value of capacitor Ca1, while it is not limited thereto. In one embodiment, the capacitance value of the capacitor Ca1 may be equal to the capacitance value of the capacitor Ca2, while it is not limited thereto.

As a result, each array unit P of the electronic device 1 may synchronously update the data corresponding to the frame time Frame1 in the writing period P2 of the frame time Frame2. Therefore, the examples of FIG. 5 and FIG. 6A may solve the problem of uneven data update in the prior art, or may achieve overall data update without delay. Alternatively, the electronic device 1 may store the data signals DS(1)˜DS(m) corresponding to the next frame time Frame2 in the capacitor Ca1 of each array unit P while updating the overall data corresponding to the frame time Frame1, which may improve the operating efficiency of the electronic device 1, but it is not limited thereto.

Please refer to FIG. 6B. The timing of the scan signals SS(1)˜SS(n) and the first signal V1 of the example of FIG. 6B may be generally applicable to the description of the example of FIG. 6A, and the data signals DS(1)˜DS(m) of FIG. 6B may be sequentially changed from a low voltage level to a high voltage level and then sequentially changed from a high voltage level to a low voltage level during the period when the scan signals SS(1)˜SS(n) in the writing period P1 are changed to a high voltage level. With such a design, the electronic device 1 may achieve the same or similar effects as the example in FIG. 6A, so as to solve the problems of the prior art.

According to the examples of FIG. 6A and FIG. 6B, each array unit P in the electronic device 1 of FIG. 5 may be operated by an operation method for an electronic device according to an embodiment of the present application, wherein the operation method for an electronic device may include the following steps:
Step C1: providing a transistor T2 including a first end b1, a second end b2 and a control end b3;
Step C2: providing a power consuming device 10 electrically connected to the first end b1 of the transistor T2;
Step C3: providing a signal source 20 electrically connected to the second end b2 of the transistor T2, and electrically connected to the control end c3 of the transistor T3;
Step C4: in the frame time Frame1 having the writing period P1 and the output period P0, the signal source 20 providing a high voltage level V1_H in the writing period P1; and
Step C5: enabling the signal source 20 to provide a low voltage level V1_L in the output period P0, and enabling the signal source 20 to provide a high voltage level V1_H in the writing period P1 of the next frame time Frame2.

In addition, in one embodiment, the operation method for an electronic device may further include step C6: providing a scan signal (for example, SS(1)), wherein the voltage level of the scan signal (for example, SS(1)) in the output period P0 is zero. In one embodiment, the operation method for an electronic device may further include step C7: providing a data signal (for example, DS(1)), wherein the voltage level of the data signal (for example, DS(1)) in the output period P0 is zero.

The order of the above steps C1 to C7 is not limited, as long as it is reasonable and achievable.

In addition, as long as it is reasonably achievable, the detailed features of the timing of each signal in the examples of FIG. 6A and FIG. 6B may be applicable to the description of the examples of FIG. 2A and FIG. 2B.

Accordingly, the examples of FIG. 5 to FIG. 6B can be understood.

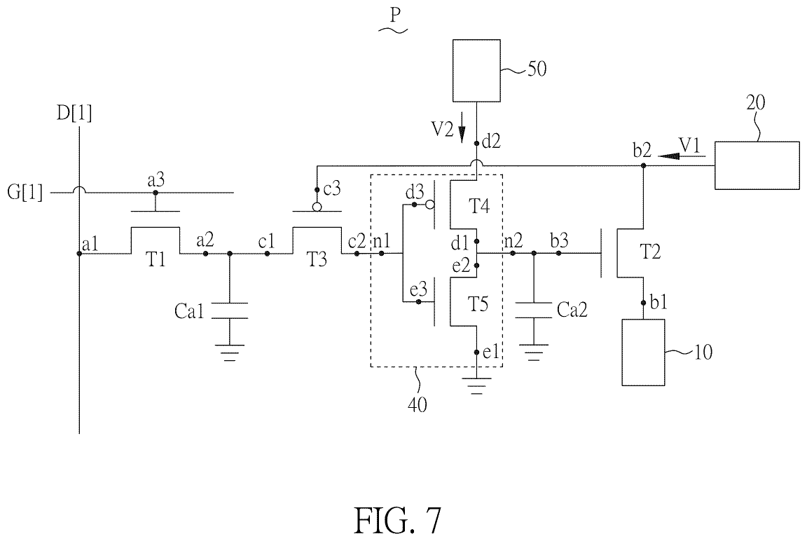

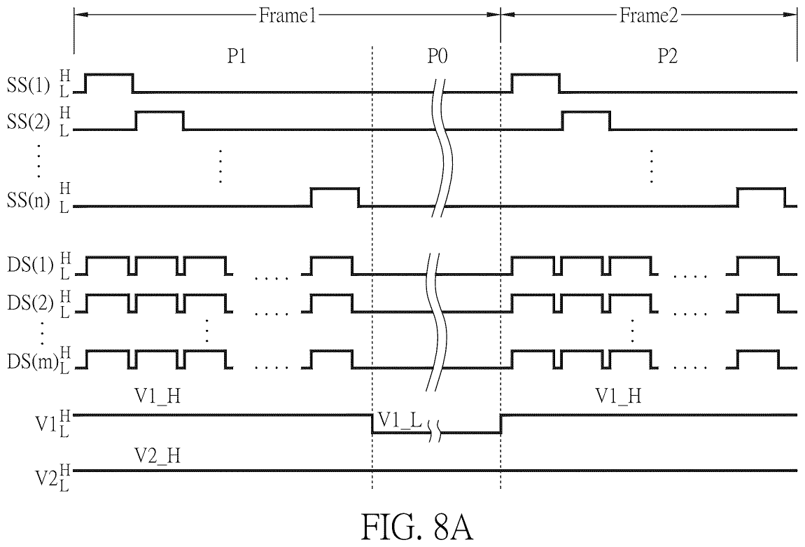

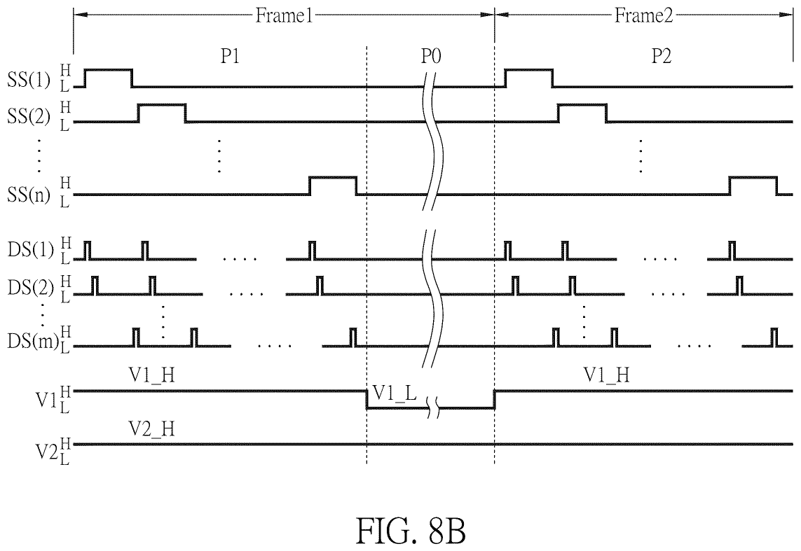

The electronic device 1 of the present application may also have different implementation aspects. FIG. 7 is a schematic diagram of an electronic device 1 according to another embodiment of the present application, FIG. 8A and FIG. 8B are timing diagrams of the scan signals SS(1)˜SS(N), the data signals DS(1)˜DS(m), the first signal V1 and the second signal V2 corresponding to FIG. 7 according to an embodiment of the present application, and please also refer to FIG. 1 to FIG. 6B. For the convenience of explanation, FIG. 7 illustrates the circuit structure of an array unit P as an example, and those skilled in the art may infer the circuit state when a plurality of array units P of FIG. 7 are formed into an array based on FIG. 1 and FIG. 7. In addition, the circuit structure of the array unit P in the example of FIG. 7 is generally applicable to the description in the example of FIG. 5, and thus the following mainly describes the differences.

As shown in FIG. 7, each array unit P may include a transistor T1, a transistor T2, a transistor T3, a capacitor Ca1, a capacitor Ca2, and a power consuming device 10, and may also include an inverter 40. The inverter 40 may be electrically connected to a signal source 50. The inverter 40 has an input node n1 and an output node n2. In one embodiment, the inverter 40 may include a transistor T4 and a transistor T5. The transistor T4 has a first end d1, a second end d2, and a control end d3. The transistor T5 has a first end e1, a second end e2, and a control end e3. The transistor T4 and the transistor T5 may have different structures. For example, the transistor T4 may have a PMOS structure, and the transistor T5 may have an NMOS structure, but it is not limited thereto. In addition, the signal source 20 may be used to provide a first signal V1, and the signal source 50 may be used to provide a second signal V2. In one embodiment, the second signal V2 may be, for example, a high voltage level signal VDD, but it is not limited thereto.

In one embodiment, the first end b1 of the transistor T2 may be electrically connected to the power consuming device 10, the second end b2 of the transistor T2 may be electrically connected to the signal source 20 to receive the first signal V1, and the control end b3 of the transistor T2 may be electrically connected to the capacitor Ca2 and the output node n2 of the inverter 40. The input node n1 of the inverter 40 may be electrically connected to the second end c2 of the transistor T3. The first end c1 of the transistor T3 may be electrically connected to the capacitor Ca1 and the second end a2 of the transistor T1, and the control end c3 of the transistor T3 may be electrically connected to the signal source 20 to receive the first signal V1. The first end a1 of the transistor T1 may be electrically connected to one of the data lines D[1]˜D[m](for example, D[1]) to receive one of the data signals DS(1)˜DS(m) (for example, DS(1)). The control end a3 of the transistor T1 may be electrically connected to one of the scan lines G[1]˜G[n](for example, G[1]) to receive one of the scan signals SS(1)˜SS(m) (for example, SS(1)). In addition, in one embodiment, the first end d1 of the transistor T4 of the inverter 40 and the second end e2 of the transistor T5 may be electrically connected to the output node n2, the second end d2 of the transistor T4 may be electrically connected to the signal source 50 to receive the second signal V2, the control end d3 of the transistor T4 and the control end e3 of the transistor T5 may be electrically connected to the input node n1, and the first end e1 of the transistor T5 may be electrically connected to a low voltage level or may be grounded (for example, the voltage value may be zero).

As shown in FIG. 8A, in the writing period P1 of the frame time Frame1, the scan signals SS(1)˜SS(n) are sequentially changed from a low voltage level (marked as L) to a high voltage level (marked as H), and the data signals DS(1)˜DS(m) are synchronously changed from a low voltage level (marked as L) to a high voltage level (marked as H). The first signal V1 is a high voltage level V1_H, and the second signal V2 is a high voltage level V2_H. At this moment, for each array unit P, the transistor T3 of the PMOS structure is turned off, and the data signal DS(1)˜DS(m) received by the transistor T1 may be stored in the capacitor Ca1. In the writing period P1, the power consuming device 10 does not perform the power consumption operation corresponding to the frame time Frame1.

In the output period P0 of the frame time Frame1, the scan signals SS(1)˜SS(n) are at a low voltage level, the data signals DS(1)˜DS(m) are at a low voltage level, the first signal V1 is at a low voltage level V1_L, and the second signal V2 is at a high voltage level V2_H. At this moment, for each array unit P, the transistor T3 of the PMOS structure is turned on, and at least a portion of the energy of the data signal DS(1)˜DS(m) corresponding to the frame time Frame1 stored in the capacitor Ca1 may be transmitted to the input node n1 of the inverter 40, and the output node n2 of the inverter 40 may output a high voltage level (for example, the second signal V2_H at the second end d2 of the transistor T4) or a low voltage level (for example, the low voltage level or zero voltage at the first end e1 of the transistor T5) according to the magnitude of the data signal DS(1)˜DS(m) received by the input node n1. In addition, since the first signal V1 is a low voltage level V1_L, the low voltage level or high voltage level outputted by the output node n2 of the inverter 40 may be stored in the capacitor Ca2, and the power consuming device 10 may not obtain energy through the transistor T2 to perform the power consumption operation corresponding to the frame time Frame1. Therefore, in the output period P0, the power consuming device 10 does not perform the power consumption operation corresponding to the frame Frame1.

In the writing period P2 of the next frame time Frame2, the scan signals SS(1)˜SS(n) are at a high voltage level, the data signals DS(1)˜DS(m) are at a high voltage level, the first signal V1 is at a high voltage level V1_H, and the second signal V2 is at a high voltage level V2_H. At this moment, for each array unit P, transistor T1 is turned on again and receives the data signal DS(1)˜DS(m) corresponding to the frame time Frame2, and at the same time transistor T3 is turned off, so that the data signal DS(1)˜DS(m) corresponding to the frame time Frame2 received by transistor T1 will be stored in capacitor Ca1. In addition, the control end b3 of the transistor T2 may receive the data stored in the capacitor Ca2 during the output period P0, so that the transistor T2 is turned on, and at least a portion of the energy of the first signal V1 (for example, V1_H) may enter the power consuming device 10 through the transistor T2, so that the power consuming device 10 performs the power consumption operation corresponding to the frame time Frame1. In one embodiment, the power consumed by the power consuming device 10 may be determined according to the data level (for example, voltage value) received by the control end b3 of the transistor T2, but it is not limited thereto.

Accordingly, each array unit P of the electronic device 1 may synchronously update the data corresponding to the frame time Frame1 in the writing period P2 of the frame time Frame2. Therefore, the examples of FIG. 7 and FIG. 8A may solve the problem of uneven data update in the prior art, or may achieve overall data update without delay. Alternatively, the electronic device 1 may store the data signals DS(1)˜DS(m) corresponding to the next frame time frame2 in the capacitor Ca1 of each array unit P while updating the overall data corresponding to the frame time frame Frame1, thereby improving the operating efficiency of the electronic device 1, but it is not limited thereto.

In addition, the example of FIG. 8B is generally applicable to the description of the example of FIG. 8A, with the difference that, in the writing period P1, during the period when the scan signals SS(1)˜SS(n) are changed to a high voltage level, the data signals DS(1)˜DS(m) are sequentially changed from a low voltage level to a high voltage level, and then sequentially changed from a high voltage level to a low voltage level. With such a design, the electronic device 1 may achieve the same or similar effect as the example in FIG. 8A.

According to the examples of FIG. 8A and FIG. 8B, each array unit P in the electronic device 1 of FIG. 7 may be operated by an operation method for an electronic device according to an embodiment of the present application, wherein the operation method for an electronic device may include the following steps:
Step D1: providing a transistor T2 including a first end b1, a second end b2 and a control end b3;
Step D2: providing a power consuming device 10 electrically connected to the first end b1 of the transistor T2;
Step D3: providing a signal source 20 electrically connected to the second end b2 of the transistor T2, and electrically connected to the control end c3 of the transistor T3;
Step D4: in the frame time Frame1 having the writing period P1 and the output period P0, the signal source 20 providing a high voltage level V1_H in the writing period P1; and
Step D5: enabling the signal source 20 to provide a low voltage level V1_L in the output period P0, and enabling the signal source 20 to provide a high voltage level V1_H in the writing period P1 of the next frame time Frame2.

In addition, in one embodiment, the operation method for an electronic device may further include step D6: providing a scan signal (for example, SS(1)), wherein the voltage level of the scan signal (for example, SS(1)) in the output period P0 is zero. In one embodiment, the operation method for an electronic device may further include step D7: providing a data signal (for example, DS(1)), wherein the voltage level of the data signal (for example, DS(1)) in the output period P0 is zero.

The order of the above steps D1 to D7 is not limited, as long as it is reasonable and achievable.

Accordingly, the examples of FIG. 7 to FIG. 8B can be understood.

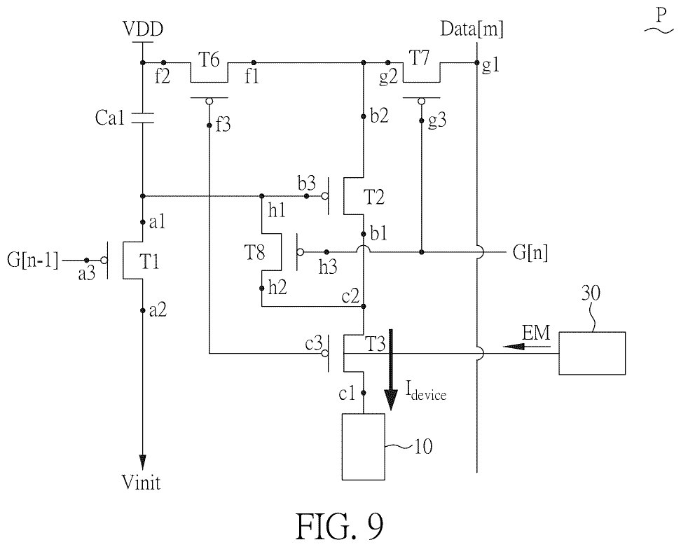

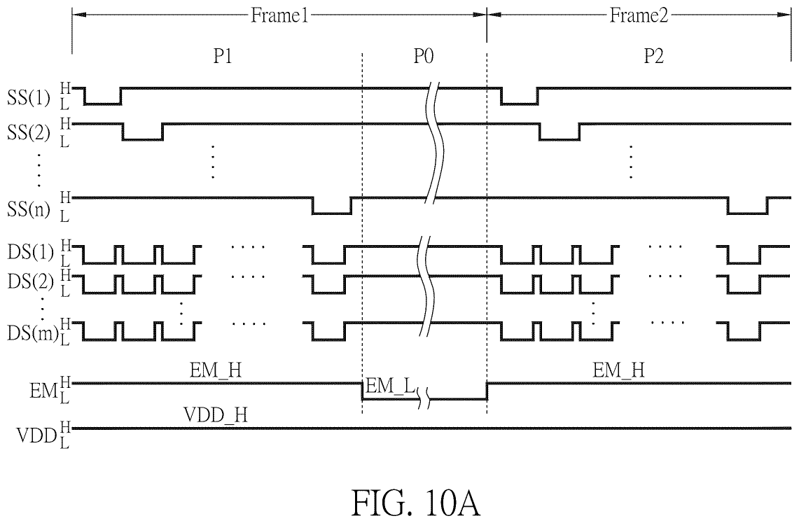

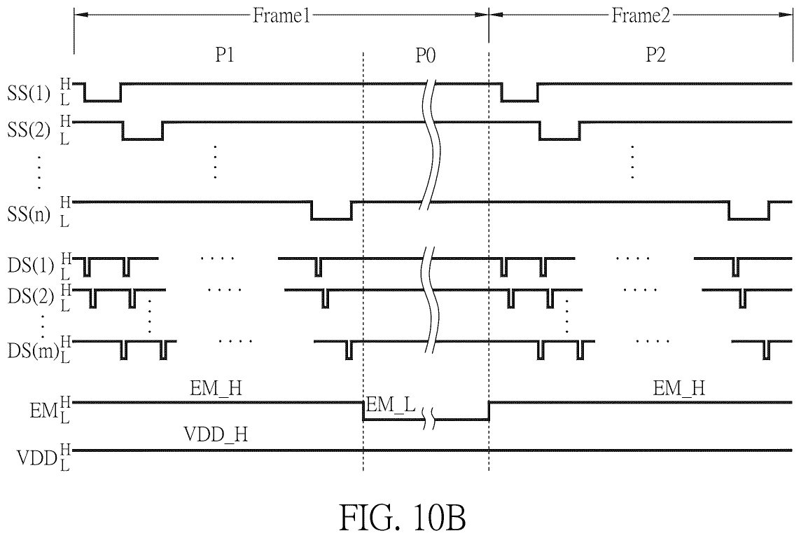

The electronic device 1 of the present application may also have different implementation aspects. FIG. 9 is a schematic diagram of an electronic device 1 according to another embodiment of the present application, FIG. 10A and FIG. 10B are timing diagrams of the scan signals SS(1)˜SS(N), data signals DS(1)˜DS(m), control signal EM and high voltage level signal VDD corresponding to FIG. 9 according to an embodiment of the present application, and please refer to FIG. 1 to FIG. 8B at the same time. For the convenience of explanation, FIG. 9 illustrates the circuit structure of an array unit P as an example, and those skilled in the art may infer the circuit state when a plurality of array units P of FIG. 9 are formed into an array based on FIG. 1 and FIG. 9.

As shown in FIG. 9, the array unit P may include a transistor T1, a transistor T2, a transistor T3, a capacitor Ca1 and a power consuming device 10, and may also include a transistor T6, a transistor T7, and a transistor T8. The transistor T6 has a first end f1, a second end f2 and a control end f3. The transistor T7 has a first end g1, a second end g2 and a control end g3. The transistor T8 has a first end h1, a second end h2 and a control end h3.

In one embodiment, the first end a1 of the transistor T1 may be electrically connected to one end of the capacitor Ca1, the first end h1 of the transistor T8 and the control end b3 of the transistor T2, the second end a2 of the transistor T1 may be electrically connected to a start signal Vinit, and the control end a3 of the transistor T1 may be electrically connected to a scan line (for example, G[n−1]). The other end of the capacitor Ca1 may be electrically connected to the high voltage level signal VDD and the second end f2 of the transistor T6. The first end b1 of the transistor T2 may be electrically connected to the second end c2 of the transistor T3 and the second end h2 of the transistor T8, and the second end b2 of the transistor T2 may be electrically connected to the first end f1 of the transistor T6 and the second end g2 of the transistor T7. The first end c1 of the transistor T3 may be electrically connected to the power consuming device 10, and the control end c3 of the transistor T3 and the control end f3 of the transistor T6 may be electrically connected to the signal source 30 to receive the control signal EM provided by the signal source 30. The first end g1 of the transistor T7 may be electrically connected to a data line (for example, D[m]), and the control end g3 of the transistor T7 and the control end h3 of the transistor T8 may be electrically connected to a scan line (for example, G[n]).

In addition, the transistors T1, T2, T3, T6, T7 and T8 in the example of FIG. 9 are exemplified by PMOS structures. Therefore, when the control end a3, b3, c3, f3, g3 or h3 of the transistor T1, T2, T3, T6, T7 or T8 receives a high voltage, the transistor T1, T2, T3, T6, T7 or T8 will be turned off, and when the control terminal a3, b3, c3, f3, g3 or h3 of the transistor T1, T2, T3, T6, T7 or T8 receives a low voltage, the transistor T1, T2, T3, T6, T7 or T8 will be turned on. It should be noted that the structures of the transistors T1, T2, T3, T6, T7 and T8 of the present application are not limited thereto.

As shown in FIG. 1, FIG. 9 and FIG. 10A, in the writing period P1 of the frame time Frame1, the scan signals SS(1)˜SS(n) are sequentially changed from a high voltage level (marked as H) to a low voltage level (marked as L), and then sequentially changed from a low voltage level to a high voltage level. The data signals DS(1)˜DS(m) are sequentially changed from a high voltage level (marked as H) to a low voltage level (marked as L), and then sequentially changed from a low voltage level to a high voltage level. The control signal EM is a high voltage level EM_H. In the output period P0 of the frame time Frame1, for each array unit P, the control signal EM may be changed from the high voltage level EM_H to the low voltage level EM_L. At this moment, at least a portion of the energy of the high voltage level signal VDD provided by the signal source 20 may enter the power consuming device 10 through the transistors T2 and T3.

In one embodiment, for an array unit P, in the first stage of the writing period P1 of the frame time Frame1, when the scan signal SS(n−1) changes from a high voltage level (H) to a low voltage level (L), the transistor T1 of the PMOS structure may be turned on. At this moment, the voltage level of the first end a1 of the transistor T1, the first end h1 of the transistor T8 and/or the control end b3 of the transistor T2 may be, for example, the voltage value of the start signal Vinit, and the energy stored in the capacitor Ca1 may be converted into a first voltage value v01, wherein the first voltage value may be, for example, the difference between the voltage value of the high voltage level signal VDD and the voltage value of the start signal Vinit (for example, v01=VDD−Vinit), while it is not limited thereto. This stage may be regarded as an initialization period of a data compensation process of the array unit P.

Next, in the second stage of the writing period P1 of the frame time Frame1, for the array unit P, when the scan signal SS(n) changes from a high level (H) to a low voltage level (L), and the scan signal SS(n−1) may change from a low level (L) to a high level (H), the transistors T7 and T8 may be turned on, and the voltage level received by the control end b3 of the transistor T2 may be affected by the transistors T7 and T8 and increased to a second voltage value v02, wherein the second voltage value may be, for example, the difference between the voltage value of the data signal DS(m) and the voltage value of the gate threshold voltage V_{t,T2} of the transistor T2 (for example, v02=DS(m)−|V_{t,T2}|), while it is not limited thereto. In addition, the energy stored in the capacitor Ca1 may be converted into a third voltage value v03, wherein the third voltage value v03 may be the difference between the voltage value of the high voltage level signal VDD and the second voltage value (for example, v03=VDD−(DS(m)−|V_{t,T2}|)), but it is not limited thereto. This stage may be regarded as a programming period of the data compensation process of the array unit P.

Next, in the output period P0 of the frame time Frame1, for the array unit P, the control signal EM may be changed from the high level EM_H to the low level EM_L, and the scan signal SS(n) may be changed from the low level (L) to the high voltage level (H). At this moment, the transistor T3 may be turned on, so that at least a portion of the energy of the high voltage level signal VDD provided by the signal source 20 may enter the power consuming device 10 through the transistors T2 and T3. This stage may be regarded as an output period of the data compensation process of the array unit P. In one embodiment, the energy entering the power consuming device 10 may be, for example, a first current value I_{device}, wherein the first current value I_{device} may be expressed as the following formula:

I_{device}=k(V_{G,T2}−|V_{t,T2}|)²=k(VDD−(DS(m)−|V_{t,T2}|)−|V_{t,T2}|)²=k(VDD−DS(m))²,

where k is, for example, a compensation parameter and may be expressed as follows:

$$K = \frac{W μ {C}_{o x}}{2 L} ;$$

$${C}_{o x} = \frac{{ε}_{o x}}{{t}_{o x}} ,$$

where tₒₓ is the thickness of the oxide layer of transistor T3, εₒₓ is the dielectric constant of the oxide layer, μ is the electron mobility, W is the width of the channel region of transistor T3, and L is the length of the channel region. The aforementioned oxide layer is, for example, a gate insulating layer in a transistor, and its materials may include inorganic materials, but it is not limited thereto.

It can be seen from this that, in the writing period P1, the power consuming device 10 does not perform power consumption operations, and in the output period P0, the power consuming device 10 of each array unit P performs power consumption operation at the same time. Therefore, with such a design, the electronic device 1 may achieve the same or similar effects as the aforementioned examples, and may solve the problems of the prior art.

In addition, the example of FIG. 10B is generally applicable to the description of the example of FIG. 10A, with the difference that, in the writing period P1, during the period when the scan signals SS(1)˜SS(n) are changed to a low voltage level, the data signals DS(1)˜DS(m) are sequentially changed from a high voltage level to a low voltage level, and then sequentially changed from a low voltage level to a high voltage level. With such a design, the electronic device 1 may achieve the same or similar effect as the example of FIG. 10A.

According to the examples of FIG. 10A and FIG. 10B, each array unit P in the electronic device 1 of FIG. 9 may be operated by an operation method for an electronic device according to an embodiment of the present application, wherein the operation method for an electronic device may include the following steps:
Step E1: providing a transistor T3 including a first end c1, a second end c2 and a control end c3;
Step E2: providing a power consuming device 10 electrically connected to the first end c1 of the transistor T3;
Step E3: providing a signal source 30 electrically connected to the control end c3 of the transistor T3 and the control end f3 of the transistor T6;
Step E4: in the frame time Frame1 having the writing period P1 and the output period P0, the signal source 30 providing a high voltage level EM_H in the writing period P1; and
Step E5: enabling the signal source 30 to provide a low voltage level EM_L in the output period P0.

In addition, in one embodiment, the operation method for an electronic device may further include step E6: providing a scan signal (for example, SS(1)), wherein the voltage level of the scan signal for example, SS(1)) in the output period P0 is not zero. In one embodiment, the operation method for an electronic device may further include step E7: providing a data signal (for example, DS(1)), wherein the voltage level of the data signal (for example, DS(1)) in the output period P0 is not zero. In one embodiment, the operation method for an electronic device may further include step E8: continuously providing the high voltage level signal VDD to the second end f2 of the transistor T6.

The order of the above steps E1 to E8 is not limited, as long as it is reasonable and achievable.

Accordingly, the examples of FIGS. 9 to 10B can be understood.

In one embodiment, the present application may determine whether a product in contention falls within the protection scope of the present application at least by the presence or absence of components, component configurations, mechanism observation and/or operating modes of the product to determine whether it falls within the protection scope of the present application, while it is not limited thereto.

The details or features of the various embodiments of the present application may be mixed and matched as long as they do not violate the spirit of the invention or conflict with each other.

With the operation method for an electronic device of the present application, the electronic device of the present application may reduce the problem of uneven overall data update, or may achieve the effect of overall data update without delay.

The aforementioned specific embodiments should be construed as merely illustrative, and not limiting the rest of the present application in any way.

1. An operation method for an electronic device, comprising steps of:
providing a first transistor having a first end and a second end;
providing a power consuming device electrically connected to the first end of the first transistor; and
providing a signal source electrically connected to the second end of the first transistor,
wherein, in a frame time including a writing period and an output period, the signal source provides a high voltage level during the output period, and the signal source provides a low voltage level during the writing period.

2. The operation method for an electronic device as claimed in claim 1, wherein a voltage value of the low voltage level is zero.

3. The operation method for an electronic device as claimed in claim 1, wherein the first transistor further includes a third end, and the third end of the first transistor is electrically connected to a first end of a second transistor.

4. The operation method for an electronic device as claimed in claim 1, further comprising a step of: providing a data signal, wherein a voltage value of a voltage level of the data signal during the output period is zero.

5. The operation method for an electronic device as claimed in claim 1, further comprising a step of: providing a scan signal, wherein a voltage value of a voltage level of the scan signal during the output period is zero.

6. The operation method for an electronic device as claimed in claim 1, wherein the first transistor further includes a third end, the third end of the first transistor is electrically connected to a first end of a second transistor and a capacitor, a second end of the second transistor is electrically connected to a first end of a third transistor and another capacitor, a second end of the third transistor is electrically connected to a data line, and a third end of the third transistor is electrically connected to a scan line.

7. The operation method for an electronic device as claimed in claim 1, wherein the first transistor further includes a third end, the third end of the first transistor is electrically connected to a node of an inverter and a capacitor, another node of the inverter is electrically connected to a first end of a second transistor, a second end of the second transistor is electrically connected to a first end of a third transistor and another capacitor, a second end of the third transistor is electrically connected to a data line, a third end of the second transistor is electrically connected to the signal source, and a third end of the third transistor is electrically connected to a scan line.

8. The operation method for an electronic device as claimed in claim 1, wherein the electronic device further includes a plurality of rows, each of the plurality of rows including a plurality of array units, wherein each of the plurality of array units includes one of a plurality of first transistors and one of a plurality of power consuming devices.

9. The operation method for an electronic device as claimed in claim 8, wherein the output period follows the writing period, each row receives a scan signal, and the scan signal received by each row has a high voltage level in the writing period.

10. The operation method for an electronic device as claimed in claim 3, wherein the third end of the first transistor is further electrically connected to a capacitor.

11. The operation method for an electronic device as claimed in claim 10, wherein a second end of the second transistor is electrically connected to a data line, and a third end of the second transistor is electrically connected to a scan line.

12. An operation method for an electronic device, comprising steps of:
providing a first transistor having a first end, a second end and a control end;
providing a power consuming device electrically connected to the second end of the first transistor; and
providing a first signal source electrically connected to the control end of the first transistor,
wherein, in a frame time including a writing period and an output period, the first signal source provides a high voltage level during the output period, and the first signal source provides a low voltage level during the writing period.

13. The operation method for an electronic device as claimed in claim 12, wherein the first end of the first transistor is electrically connected to a first end of a second transistor, a second end of the second transistor is electrically connected to a second signal source, a control end of the second transistor is electrically connected to a first end of a third transistor and a capacitor, a second end of the third transistor is electrically connected to a data line, and a control end of the third transistor is electrically connected to a scan line.

14. The operation method for an electronic device as claimed in claim 13, further comprising a step of: providing a data signal to the data line, wherein a voltage value of a voltage level of the data signal during the output period is zero.

15. The operation method for an electronic device as claimed in claim 13, further comprising a step of: providing a scan signal to the scan line, wherein a voltage value of a voltage level of the scan signal during the output period is zero.

16. The operation method for an electronic device as claimed in claim 13, further comprising a step of: enabling the second signal source to continuously provide a high voltage level signal to the second end of the second transistor.

17. The operation method for an electronic device as claimed in claim 12, wherein the electronic device further includes a plurality of rows, each of the plurality of rows includes a plurality of array units, each of the plurality of array units includes one of a plurality of first transistors and one of a plurality of power consuming devices.

18. The operation method for an electronic device as claimed in claim 17, wherein the output period follows the writing period, each row receives a scan signal, and the scan signal received by each row has a high voltage level during the writing period.

19. An operation method for an electronic device, comprising steps of:
providing a first transistor including a first end and a second end;
providing a power consuming device electrically connected to the first end of the first transistor; and
providing a signal source electrically connected to the second end of the first transistor,
wherein, in a frame time including a writing period and an output period, the signal source provides a low voltage level during the output period, and the signal source provides a high voltage level during the writing period.

20. The operation method for an electronic device as claimed in claim 19, wherein a voltage value of the low voltage level is zero.
